(19) United States
(12) Patent Application Publication
(10) Pub. No.: US 2025/0157496 A1
(43) Pub. Date: May 15, 2025

(54) SEMICONDUCTOR DEVICE

(71) Applicant: Samsung Electronics Co., Ltd., Suwon-si (KR)

(72) Inventors: Taemin Ok, Suwon-si (KR); Changyeon Yu, Suwon-si (KR); Pansuk Kwak, Suwon-si (KR)

(21) Appl. No.: 18/791,587

(22) Filed: Aug. 1, 2024

(30) Foreign Application Priority Data
Nov. 14, 2023 (KR) 10-2023-0157339

(51) Int. Cl. G11C 5/06; G11C 16/04; G11C 16/08; H10B 41/10; H10B 41/27; H10B 41/35; H10B 41/41; H10B 43/10; H10B 43/27; H10B 43/35; H10B 43/40

(52) U.S. Cl. CPC G11C 5/063; G11C 16/0483; G11C 16/08; H10B 41/10; H10B 41/27; H10B 41/35; H10B 41/41; H10B 43/10; H10B 43/27; H10B 43/35; H10B 43/40

(57) ABSTRACT

A semiconductor device includes a plurality of blocks each including a first substrate, a plurality of lower gate electrode layers stacked in a first direction perpendicular to an upper surface of the first substrate, a second substrate above the plurality of lower gate electrode layers, and a plurality of upper gate electrode layers stacked in the first direction on the second substrate; pass transistors electrically connected to the plurality of lower gate electrode layers and the plurality of upper gate electrode layers; and a row decoder electrically connected to the pass transistors, wherein a number of the plurality of lower gate electrode layers and a number of the plurality of upper gate electrode layers included in each of the plurality of blocks are greater than a number of the pass transistors.

### CROSS-REFERENCE TO RELATED APPLICATION(S)

This application claims the benefit of priority to Korean Patent Application No. 10-2023-0157339, filed Nov. 14, 2023, in the Korean Intellectual Property Office, the disclosure of which is incorporated herein by reference in its entirety.

### BACKGROUND

Example embodiments relate to semiconductor devices and more particularly to semiconductor memory devices.

A semiconductor device may provide a function of writing and erasing data or reading written data. To improve integration density of a semiconductor device, a semiconductor device having a vertical structure in which memory cells are stacked in a direction perpendicular to an upper surface of a substrate has been used.

### SUMMARY

An example embodiment of the disclosure is to provide a semiconductor device having a structure in which a first layer and a second layer are stacked, which may improve integration density by electrically isolating lower channel structures included in the first layer and upper channel structures included in the second layer from each other, and electrically connecting a portion of the lower gate electrode layers of the first layer and the upper gate electrode layers of the second layer.

According to an example embodiment of the disclosure, a semiconductor device includes a first substrate; a plurality of lower gate electrode layers stacked on an upper surface of the first substrate in a first direction perpendicular to an upper surface of the first substrate; a second substrate above the plurality of lower gate electrode layers; a plurality of upper gate electrode layers stacked on the second substrate in the first direction; a plurality of lower channel structures extending in the first direction, extending through the plurality of lower gate electrode layers, and electrically connected to the first substrate; a plurality of upper channel structures extending in the first direction, extending through the plurality of upper gate electrode layers, electrically connected to the second substrate, and electrically isolated from the plurality of lower channel structures; a plurality of lower bitlines electrically connected to the plurality of lower channel structures and extending in a second direction parallel to the upper surface of the first substrate; and a plurality of upper bitlines connected to the plurality of upper channel structures and extending in the second direction, wherein the plurality of lower bitlines and the plurality of upper bitlines are in different positions in a third direction parallel to the upper surface of the first substrate and intersecting the second direction.

According to an example embodiment of the disclosure, a semiconductor device includes a cell array region including a plurality of lower channel structures extending through a plurality of lower gate electrode layers stacked in a first direction, and a plurality of upper channel structures extending through a plurality of upper gate electrode layers stacked in the first direction and electrically isolated from the plurality of lower channel structures; and a cell contact region including a plurality of cell contacts electrically connected to the plurality of lower gate electrode layers and the plurality of upper gate electrode layers, wherein an nth lower gate electrode layer positioned nth in the first direction among the plurality of lower gate electrode layers and a nth upper gate electrode layer positioned nth in the first direction among the plurality of upper gate electrode layers are electrically connected to one of the plurality of cell contacts.

According to an example embodiment of the disclosure, a semiconductor device includes a plurality of blocks each including a first substrate, a plurality of lower gate electrode layers stacked in a first direction perpendicular to an upper surface of the first substrate, a second substrate above the plurality of lower gate electrode layers, and a plurality of upper gate electrode layers stacked in the first direction on the second substrate; pass transistors electrically connected to the plurality of lower gate electrode layers and the plurality of upper gate electrode layers; and a row decoder electrically connected to the pass transistors, wherein a number of the plurality of lower gate electrode layers and a number of the plurality of upper gate electrode layers included in each of the plurality of blocks are greater than a number of the pass transistors.

### BRIEF DESCRIPTION OF DRAWINGS

The above and other aspects, features, and advantages in the example embodiments will be more clearly understood from the following detailed description, taken in combination with the accompanying drawings, in which:

FIG. 1 is a diagram illustrating a memory system including a semiconductor device according to an example embodiment of the present disclosure;

FIG. 2 is a block diagram illustrating a semiconductor device according to an example embodiment of the present disclosure;

FIG. 3 is a circuit diagram illustrating a memory cell array included in a semiconductor device according to an example embodiment of the present disclosure;

FIG. 4 is a diagram illustrating a structure of a cell region included in a semiconductor device according to an example embodiment of the present disclosure;

FIGS. 5 and 6 are diagrams illustrating a region of a first stack structure included in a semiconductor device according to an example embodiment of the present disclosure;

FIGS. 7 and 8 are diagrams illustrating a region of a second stack structure included in a semiconductor device according to an example embodiment of the present disclosure;

FIGS. 9 and 10 are diagrams illustrating a region of a semiconductor device according to an example embodiment of the present disclosure;

FIGS. 11A and 11B are cross-sectional diagrams illustrating a region of a semiconductor device according to an example embodiment of the present disclosure;

FIG. 12 is a cross-sectional diagram illustrating a region of a semiconductor device according to an example embodiment of the present disclosure;

FIG. 13 is a plan diagram illustrating a first layer included in a semiconductor device according to an example embodiment of the present disclosure;

FIG. 14 is a plan diagram illustrating a second layer included in a semiconductor device according to an example embodiment of the present disclosure;

FIG. 15 is a plan diagram illustrating a region of a semiconductor device according to an example embodiment of the present disclosure;

FIGS. 16 and 17 are diagrams illustrating operations of a semiconductor device according to an example embodiment of the present disclosure;

FIG. 18 is a diagram illustrating a memory device according to an example embodiment of the present disclosure; and

FIGS. 19 and 20 are diagrams illustrating a memory device according to an example embodiment of the present disclosure.

### DETAILED DESCRIPTION

Hereinafter, embodiments in the example embodiment will be described as follows with reference to the accompanying drawings.

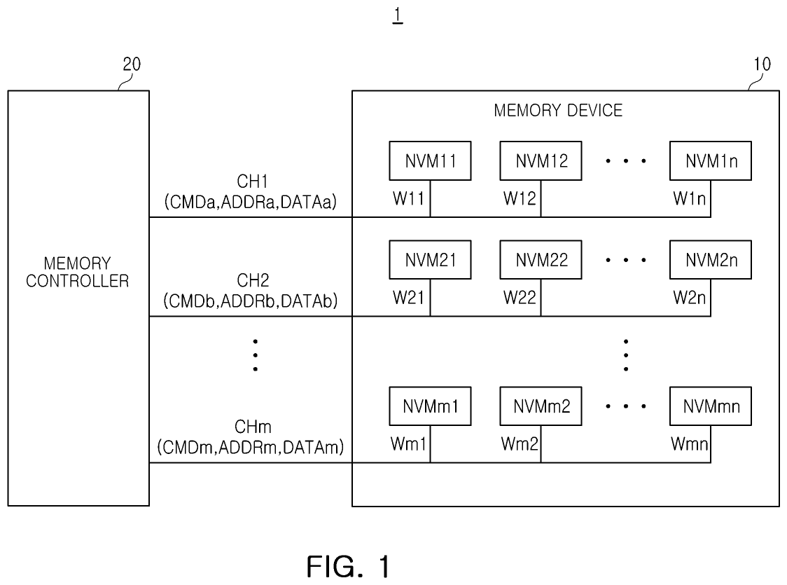

FIG. 1 is a diagram illustrating a memory system including a semiconductor device according to an example embodiment.

Referring to FIG. 1, a memory system 1 according to an example embodiment may include at least one memory device 10 and a memory controller 20. A semiconductor device according to an example embodiment may be configured as the memory device 10, which may be applied to the memory system 1 and may be configured to store data. The memory device 10 may be a NAND flash memory, and may, in some embodiments, be a vertical NAND flash memory in which memory cells are disposed in a direction parallel to an upper surface of the substrate, and also in a direction perpendicular to an upper surface of the substrate in an example embodiment. Accordingly, the memory device 10 may be implemented as a three-dimensional array structure.

The memory device 10 and the memory controller 20 may be connected through a plurality of channels CH1-CHm. For example, the memory system 1 may be implemented as a storage device, such as a solid state drive (SSD).

The memory device 10 may include a plurality of the memory chips NVM11-NVMmn. Each of the memory chips NVM11-NVMmn may be connected to one of the plurality of channels CH1-CHm through a corresponding way. For example, the memory devices NVM11-NVM1n may be connected to the first channel CH1 through ways W11-W1n, and the memory devices NVM21-NVM2n may be connected to the second channel CH2 through ways W21-W2n. In an example embodiment, each of the memory chips NVM11-NVMmn may be implemented as an arbitrary memory unit for operating according to individual instructions from the memory controller 20. For example, each of the memory chips NVM11-NVMmn may be implemented as a chip or a die, but an example embodiment thereof is not limited thereto.

The memory controller 20 may transmit signals to and receive signals from the memory device 10 through the plurality of channels CH1-CHm. For example, the memory controller 20 may transmit commands CMDa-CMDm, addresses ADDRa-ADDRm, and data DATAa-DATAm to the memory device 10 through the channels CH1-CHm, or may transmit the data DATAa-DATAm from the memory device 10.

The memory controller 20 may select one of the nonvolatile memory devices connected to the corresponding channel through each channel and may transmit signals to and may receive signals from the selected nonvolatile memory device. For example, the memory controller 20 may select a nonvolatile memory device NVM11 from among the memory devices NVM11-NVM1n connected to a first channel CH1. The memory controller 20 may transmit a command CMDa, an address ADDRa, and data DATAa to the selected memory device NVM11 through the first channel CH1, or may receive data DATAa from the selected memory device NVM11.

The memory controller 20 may transmit signals to and may receive signals from the memory device 10 in parallel through different channels. For example, the memory controller 20 may transmit the command CMDb to the memory device 10 through a second channel CH2 while transmitting the command CMDa to the memory device 10 through the first channel CH1. For example, the memory controller 20 may receive data DATAb from the memory device 10 through the second channel CH2 while receiving data DATAa from the memory device 10 through the first channel CH1.

The memory controller 20 may control overall operations of the memory device 10. The memory controller 20 may control each of the memory chips NVM11-NVMmn connected to the channels CH1-CHm by transmitting a signal to the channels CH1-CHm, respectively. For example, the memory controller 20 may control a selected one of the memory devices NVM11-NVM1n by transmitting the command CMDa and the address ADDRa to the first channel CH1.

Each of the memory chips NVM11-NVMmn may operate under control of the memory controller 20. For example, the memory device NVM11 may program data DATAa according to the command CMDa, the address ADDRa, and the data DATAa provided through the first channel CH1. For example, the memory device NVM21 may read-out data DATAb according to the command CMDb and the address ADDRb provided through the second channel CH2, and may transmit the read-out data DATAb to the memory controller 20.

In FIG. 1, the memory device 10 may communicate with the memory controller 20 through m number of channels, and the memory device 10 may include n number of nonvolatile memory devices corresponding to the channels, respectively, but the number of channels and the number of nonvolatile memory devices connected to a channel may be varied according to different embodiments.

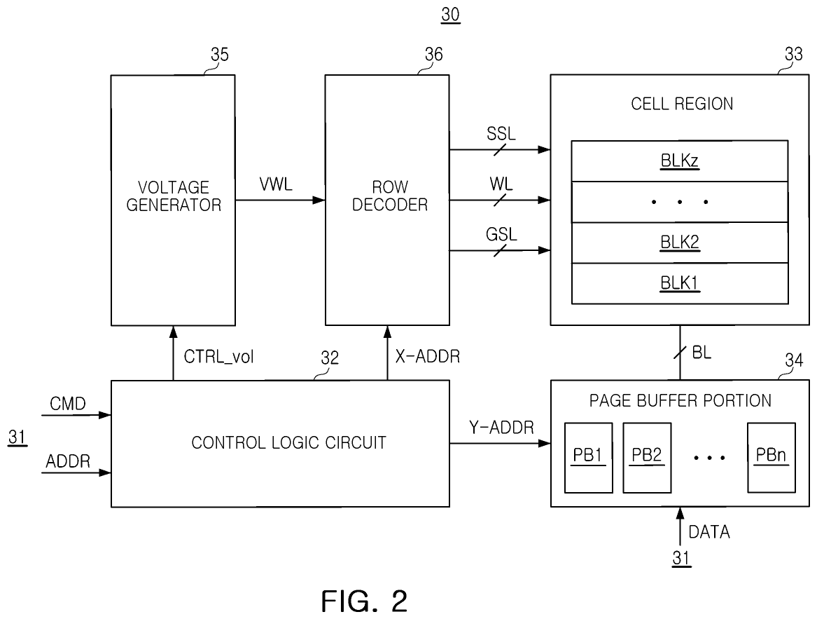

FIG. 2 is a block diagram illustrating a semiconductor device according to an example embodiment.

Referring to FIG. 2, the semiconductor device 30 may include a control logic circuit 32, a cell region 33, a page buffer portion 34, a voltage generator 35, and a row decoder 36. The semiconductor device 30 may further include an interface circuit 31, and may further include a column logic, a pre-decoder, a temperature sensor, a command decoder, an address decoder, a source driver, or the like. The semiconductor device 30 may be implemented as a memory device for storing data, and may be implemented as a nonvolatile memory device maintaining stored data even when power is turned off, for example.

The control logic circuit 32 may generally control various operations in the semiconductor device 30. The control logic circuit 32 may output various control signals in response to a command CMD and/or address ADDR received by an interface circuit 31. For example, the control logic circuit 32 may output a voltage control signal CTRL_vol, a row address X-ADDR, and a column address Y-ADDR.

The cell region 33 may include a plurality of the memory blocks BLK1-BLKz (z is a positive integer), and each of the plurality of the memory blocks BLK1-BLKz may include a plurality of the memory cells. In an example embodiment, a plurality of the memory blocks BLK1-BLKz may be electrically isolated from each other by first isolation regions including an insulating material, and second isolation regions other than the first isolation regions may be disposed in each of the plurality of the memory blocks BLK1-BLKz. For example, the second isolation regions may have a structure different from that of the first isolation region.

For example, the plurality of the memory blocks BLK1-BLKz may include main blocks for storing data, and at least one spare block for storing data used for operation of the semiconductor device 30. The cell region 33 may be electrically connected to a page buffer portion 34 through bitlines BL, and may be electrically connected to a row decoder 36 through wordlines WL, string select lines SSL, and ground select lines GSL.

In an example embodiment, the cell region 33 may include a three-dimensional memory cell array, and the three-dimensional memory cell array may include a plurality of NAND strings. Each NAND string may include memory cells connected to wordlines stacked vertically on the substrate, respectively. U.S. Pat. Nos. 7,679,133, 8,553,466, 8,654,587, 8,559,235, and U.S. Patent Publication No. 011/0233648 are incorporated herein by reference as examples. In an example embodiment, the cell region 33 may include a two-dimensional memory cell array, and the two-dimensional memory cell array may include a plurality of NAND strings arranged in row and column directions.

The page buffer portion 34 may include a plurality of page buffers PB1-PBn (n is an integer of 3 or more), and the plurality of page buffers PB1-PBn may be electrically connected to the memory cells through the plurality of bitlines BL, respectively. The page buffer portion 34 may select at least one bitline among the bitlines BL in response to the column address Y-ADDR. The page buffer portion 34 may operate as a write driver or a sense amplifier depending on an operation mode. For example, during a program operation, the page buffer portion 34 may apply a bitline voltage corresponding to data to be programmed to the selected bitline. During a read operation, the page buffer portion 34 may sense the data stored in the memory cell by sensing a current or voltage of the selected bitline. Data to be programmed into the cell region 33 through a program operation and data read from the cell region 33 through a read operation may be input and output through interface circuit 31.

The voltage generator 35 may generate various types of voltages to perform program, read, and erase operations based on the voltage control signal CTRL_vol. For example, the voltage generator 35 may generate a program voltage, a read voltage, a pass voltage, a program verification voltage, an erase voltage, or the like. In an example embodiment, the control logic circuit 32 may control the voltage generator 35 to generate voltages for executing program, read, and erase operations using data stored in a spare block. A portion of the voltages generated by the voltage generator 35 may be input to the wordlines WL as wordlines voltage VWL by the row decoder 36, and a portion thereof may be input to a common source line by a source driver.

The row decoder 36 may select one of the plurality of wordlines WL and one of the plurality of string select lines SSL in response to the row address X-ADDR. For example, during a program operation, the row decoder 36 may apply the program voltage and program verification voltage to the selected wordline, and during read operation, the row decoder 36 may apply the read voltage to the selected wordline.

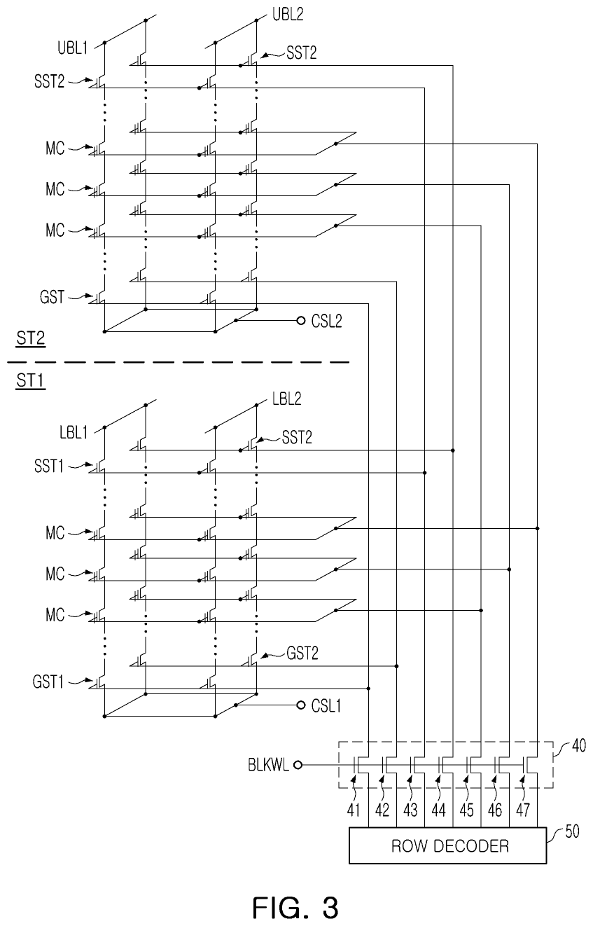

FIG. 3 is a circuit diagram illustrating a memory cell array included in a semiconductor device according to an example embodiment.

Referring to FIG. 3, a memory cell array of a semiconductor device according to an example embodiment may include a first stack structure ST1 and a second stack structure ST2 stacked with each other. A plurality of NAND strings may be disposed in each of the first stack structure ST1 and the second stack structure ST2, and each of the plurality of NAND strings may include select transistors GST1-GST2, SST1-SST2 and memory cells MC. The plurality of NAND strings disposed in each of the first stack structure ST1 and the second stack structure ST2 may be included in a block.

The plurality of NAND strings included in the first stack structure ST1 may be electrically connected to the first common source line CSL1 and the plurality of lower wordlines LWL. Also, each of the plurality of NAND strings included in the first stack structure ST1 may be connected to the first lower bitline LBL1 or the second lower bitline LBL2. The plurality of lower wordlines LWL may be electrically connected to a row decoder 50 through a pass element portion 40, and a first lower bitline LBL1 and a second lower bitline LBL2 may be electrically connected to a page buffer.

The plurality of NAND strings included in the second stack structure ST2 may be electrically connected to the second common source line CSL2 and the plurality of upper wordlines UWL. Also, each of the plurality of NAND strings included in the second stack structure ST2 may be electrically connected to a first upper bitline UBL1 or a second upper bitline UBL2. The plurality of upper wordlines UWL may be electrically connected to a row decoder 50 through the pass element portion 40, and the first upper bitline UBL1 and the second lower bitline UBL2 may be electrically connected to the page buffer.

In an example embodiment, as illustrated in FIG. 3, the plurality of upper wordlines UWL and the plurality of lower wordlines LWL may share the plurality of pass transistors 41-47 included in the pass element portion 40. For example, the fifth pass transistor 45 may be commonly electrically connected to one of the plurality of upper wordlines UWL and the plurality of lower wordlines LWL.

When the pass transistors 41-47 are turned on by the block selection signal BLKWL, the bias voltage output by the row decoder 50 may be commonly input to the first stack structure ST1 and the second stack structure ST2. In an example embodiment, the lower bitlines LBL1-LBL2, which are electrically connected to the plurality of NAND strings in the first stack structure ST1, and the upper bitlines UBL1-UBL2, which are electrically connected to the plurality of NAND strings in the second stack structure ST2, may be electrically isolated from each other. For example, the page buffer to which the lower bitlines LBL1-LBL2 are electrically connected may be different from the page buffer to which the upper bitlines UBL1-UBL2 are electrically connected. Accordingly, although the plurality of upper wordlines UWL and the plurality of lower wordlines LWL share the plurality of pass transistors 41-47, the memory cells MC included in each of the first stack structure ST1 and the second stack structure ST2 may be controlled independently.

To connect the lower bitlines LBL1-LBL2 and the upper bitlines UBL1-UBL2 to different page buffers, in an example embodiment, the channel structures providing the plurality of NAND strings in the first stack structure ST1 may be electrically isolated from each other without being connected to the channel structures providing the plurality of NAND strings in the second stack structure ST1. Also, to electrically connect the lower bitlines LBL1-LBL2 disposed in the first stack structure ST1 with the page buffer, at least a portion of region of the second stack structure ST2 may be allocated as an arrangement space for lower bitline contacts electrically connecting the lower bitlines LBL1-LBL2 to the page buffer.

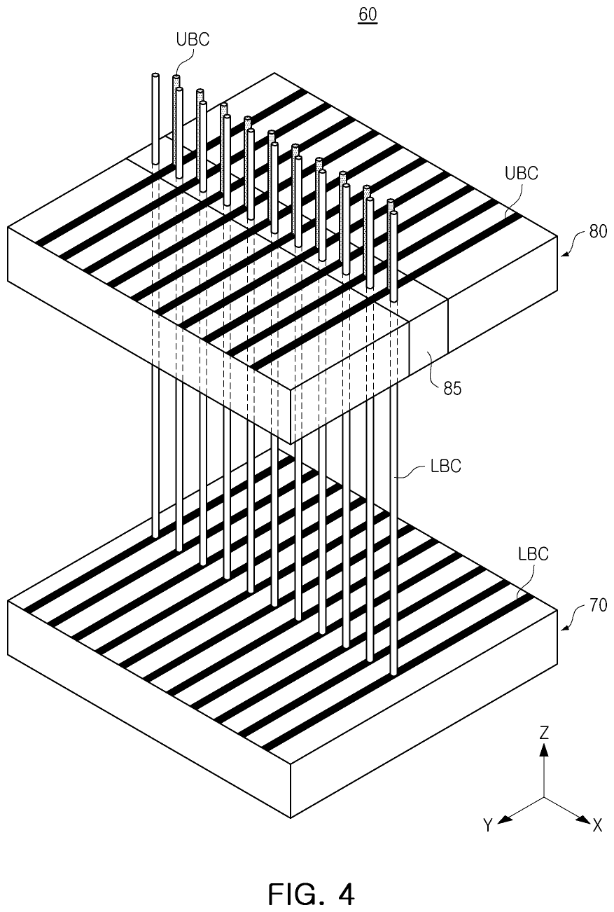

FIG. 4 is a diagram illustrating a structure of a cell region included in a semiconductor device according to an example embodiment.

Referring to FIG. 4, a cell region of the semiconductor device 60 according to an example embodiment may include a first stack structure 70 and a second stack structure 80 stacked with each other in the first direction (Z-axis direction). The first stack structure 70 may include a plurality of lower gate electrode layers providing a plurality of lower wordlines, a plurality of lower channel structures penetrating through or extending into a plurality of lower gate electrode layers, and a plurality of lower bitlines LBL electrically connected to a plurality of lower channel structures. The second stack structure 80 may include a plurality of upper gate electrode layers providing a plurality of upper wordlines, a plurality of upper channel structures penetrating through or extending into a plurality of upper gate electrode layers, and a plurality of upper bitlines LBL electrically connected to a plurality of upper channel structures.

In an example embodiment, a plurality of lower gate electrode layers and a plurality of upper gate electrode layers may share pass transistors. Accordingly, when the pass transistors are turned on to execute a program operation, a read operation, or the like, the memory cell included in the first stack structure 70 and the memory cell included in the second stack structure 80 may be selected together.

To prevent a program operation, a read operation, or the like, from being unintentionally executed simultaneously in the memory cells included in the first stack structure 70 and the memory cells included in the second stack structure 80, in an example embodiment, the plurality of lower channel structures and the plurality of upper channel structures may be electrically isolated from each other. To this end, as illustrated in FIG. 4, the plurality of lower bitlines LBL may be electrically connected to the plurality of lower bitline contacts LBC, and the plurality of upper bitlines UBL may be electrically connected to the plurality of upper bitline contacts UBC. The plurality of lower bitline contacts LBC and the plurality of upper bitline contacts UBC may be electrically isolated from each other.

For example, referring to FIG. 4, the plurality of lower bitlines LBL and the plurality of upper bitlines UBL may extend in the second direction (Y-axis direction) and may be arranged in the third direction (X-axis direction). The plurality of lower bitlines LBC connected to the plurality of lower bitlines LBL may penetrate through or extend into the second stack structure 80 and may extend in the first direction.

To prevent plurality of lower bitline contacts LBC from being connected to the plurality of upper bitlines UBL, the plurality of lower bitlines LBL and the plurality of upper bitlines UBL may be disposed in different positions in the third direction. For example, in an example embodiment illustrated in FIG. 4, the plurality of lower bitlines LBL and the plurality of upper bitlines UBL may be disposed alternately in the third direction.

The plurality of lower bitline contacts LBC may penetrate through or extend into the through-contact region 85 included in the second stack structure 80 and may extend in the first direction. The plurality of upper gate electrode layers and the plurality of upper channel structures may not be disposed in the through-contact region 85, and memory cells may not be disposed in the through-contact region 85. Accordingly, the plurality of lower bitline contacts LBC may be electrically isolated from the memory cells included in the second stack structure 80. The plurality of lower bitline contacts LBC may extend a space in the first direction between the plurality of upper bitlines UBL, taken in the third direction.

Meanwhile, the plurality of upper bitline contacts UBC may extend in the first direction and may be electrically connected to the plurality of upper bitlines UBL. In an example embodiment illustrated in FIG. 4, the plurality of upper bitline contacts UBC may be disposed in the upper through-region 85 similarly to the plurality of lower bitline contacts LBC, but an example embodiment thereof is not limited thereto. For example, the plurality of upper bitline contacts UBC may be disposed in a position different from the plurality of lower bitline contacts LBC in the second direction, or may be disposed in a position not overlapping the upper through-region 85 in the first direction.

Also, in example embodiments, the plurality of lower bitlines LBL and the plurality of upper bitlines UBL may be disposed in the same position in the third direction. In this case, the plurality of lower bitlines LBL and the plurality of upper bitlines UBL may overlap each other in the first direction. The plurality of lower bitline contacts LBC may be disposed between the plurality of upper bitlines UBL in the third direction, as in an example embodiment illustrated in FIG. 4, and may be connected to the plurality of lower bitlines LBL by wiring patterns included in the first stack structure ST1.

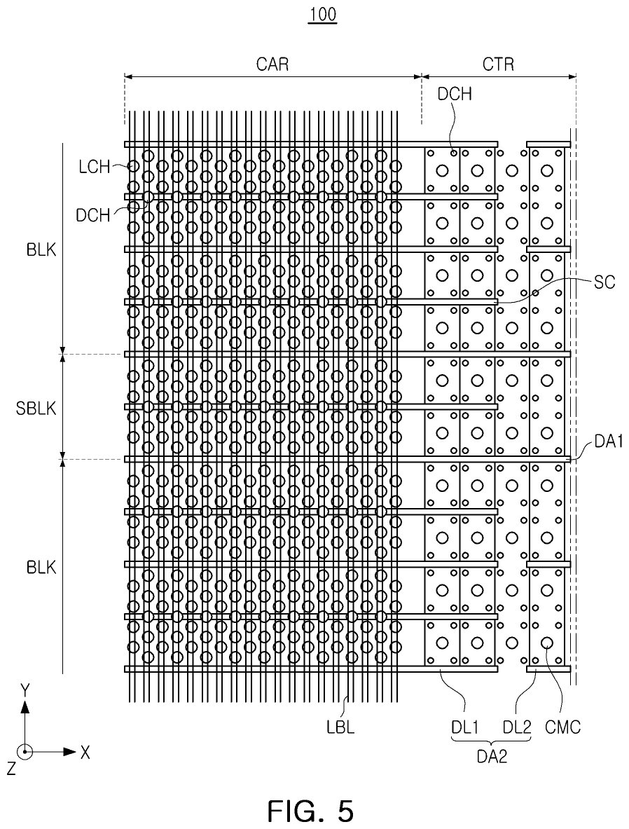

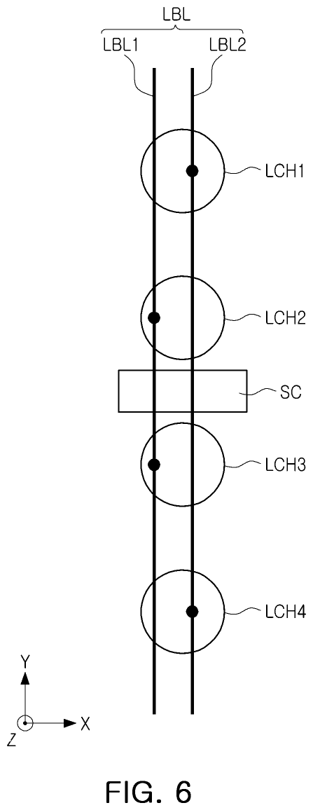

FIGS. 5 and 6 are diagrams illustrating a region of a first stack structure included in a semiconductor device according to an example embodiment.

FIG. 5 is a plan diagram illustrating a portion of the first stack structure included in the semiconductor device 100 according to an example embodiment. Referring to FIG. 5, the first stack structure of the semiconductor device 100 may provide a cell region in which memory cells are disposed, and the cell region may include a cell array region CAR and a cell contact region CTR. For example, the cell array region CAR may be a region in which the lower channel structures LCH are disposed, and the cell contact region CTR may be a region in which the cell contacts CMC connected to the lower gate electrode layers are disposed.

In the cell region, a plurality of lower gate electrode layers stacked in the first direction (Z-axis direction), and a plurality of lower channel structures LCH extending in the first direction and penetrating through or extending into the plurality of lower gate electrode layers may be disposed. The plurality of lower gate electrode layers may be formed of conductive materials, such as metal and metal silicide, and each of the plurality of channel structures CH may include a channel layer, a charge storage layer, a tunneling layer, and a blocking layer.

The cell region may include a plurality of blocks BLK arranged in the second direction (Y-axis direction), and the plurality of blocks BLK may be distinct from each other by a plurality of first isolation regions DA1 extending in the third direction (X-axis direction). Each of the plurality of first isolation regions DA1 may extend in the second direction, may cross the cell region, and may include an insulating material. For example, each of the plurality of first isolation regions DA1 may be formed of silicon oxide, silicon nitride, or the like.

Meanwhile, at least one second isolation region DA2 may be disposed in each of the plurality of blocks BLK. The plurality of second isolation regions DA2 may extend in the third direction similarly to the plurality of first isolation regions DA1, and may be disposed in one of the plurality of blocks BLK, rather than at a boundary between the plurality of blocks BLK. In an example embodiment illustrated in FIG. 5, each of the plurality of blocks BLK may include at least two second isolation regions DA2, but the number of second isolation regions DA2 included in each of the plurality of blocks BLK may be varied in example embodiments.

Referring to FIG. 5, each of the plurality of second isolation regions DA2 may be isolated into a first line DL1 and a second line DL2 in the third direction. The first line DL1 and the second line DL2 may be isolated without being electrically connected to each other in the third direction. Accordingly, through a region between the first line DL1 and the second line DL2, a portion of the plurality of lower gate electrode layers may be electrically connected as an integrated layer in each of the plurality of blocks BLK.

For example, among the plurality of lower gate electrode layers, lower gate electrode layers providing the plurality of lower wordlines may be connected to each other between the first line DL1 and the second line DL2. For example, a lower gate electrode layer disposed on a first level in the first direction and providing one of the lower wordlines may be interconnected between the first line DL1 and the second line DL in the second direction in each of the plurality of blocks BLK, and may not be divided into a plurality of regions in the second direction in each plurality of blocks BLK. In other words, in each of the plurality of blocks BLKs, there may be only one lower gate electrode layer disposed on a specific level.

The lower gate electrode layers providing the lower string select line may be divided into a plurality of regions in the second direction by the first line DL1 and an upper isolation layer SC in each of the plurality of blocks BLK. A portion of the lower gate electrode layers providing the ground select line may be connected to each other in each of the plurality of blocks BLK. In an example embodiment, a ground select line may be provided by a lower gate electrode layer below the lower gate electrode layers isolated from each other in the second direction by the upper isolation layer SC and provide string select lines. In this example, the number of string select lines disposed in a block BLK may be greater than the number of ground select lines.

Referring to FIG. 5, a plurality of dummy channel structures DCH may be disposed in the cell array region CAR and the cell contact region CTR. The plurality of dummy channel structures DCH may be electrically isolated without being electrically connected to the plurality of lower bitlines LBL and accordingly, the dummy channel structures DCH may not be involved in operation of the semiconductor device 100.

A plurality of lower bitlines LBL may extend in the second direction and may be arranged in the third direction. Each of the plurality of lower bitlines LBL may be disposed to overlap at least a portion of the plurality of lower channel structures LCH in the first direction. For example, each of the plurality of lower bitlines LBL may be electrically connected to two or more of the lower channel structures LCH. Accordingly, two or more lower channel structures LCH may be commonly connected to one of the lower bitlines LBL.

Referring to FIG. 6, among the plurality of lower bitlines LBL, the first lower bitline LBL1 and the second lower bitline LBL2 may be disposed adjacently to each other in the third direction. In the first direction, a plurality of lower channel structures LCH1-LCH4 may be disposed below the first lower bitline LBL1 and the second lower bitline LBL2 as shown in FIG. 6.

Among the plurality of lower channel structures LCH1-LCH4 illustrated in FIG. 6, the first and second lower channel structures LCH1 and LCH2 may be disposed on one side of the upper isolation layer SC in the second direction, and the third and fourth lower channel structures LCH3, LCH4 may be disposed on the other side of the upper isolation layer SC in the second direction. Referring to FIG. 6, the first and fourth lower channel structures LCH1 and LCH4 may be connected to the second lower bitline LBL2, and the second and third lower channel structures LCH2 and LCH3 may be connected to the first lower bitline LBL1.

Referring again to FIG. 5, at least one sub-block SBLK may be disposed between plurality of blocks BLK. In an example embodiment illustrated in FIG. 5, the sub-block SBLK may have a length less than that of each of the plurality of blocks BLK in the second direction, but an example embodiment thereof is not limited thereto. In example embodiments, the length of the sub-block SBLK in the second direction may be equal to the length of each of the plurality of blocks BLK.

The through-contact region of the second stack structure may be disposed on the sub-block SBLK in the first direction. In the through-contact region, the plurality of lower bitline contacts electrically connected to the plurality of lower bitlines LBL and extending in the first direction may be disposed. To dispose the plurality of lower bitline contacts, the channel structure or the gate electrode layer may not be disposed in the through-contact region.

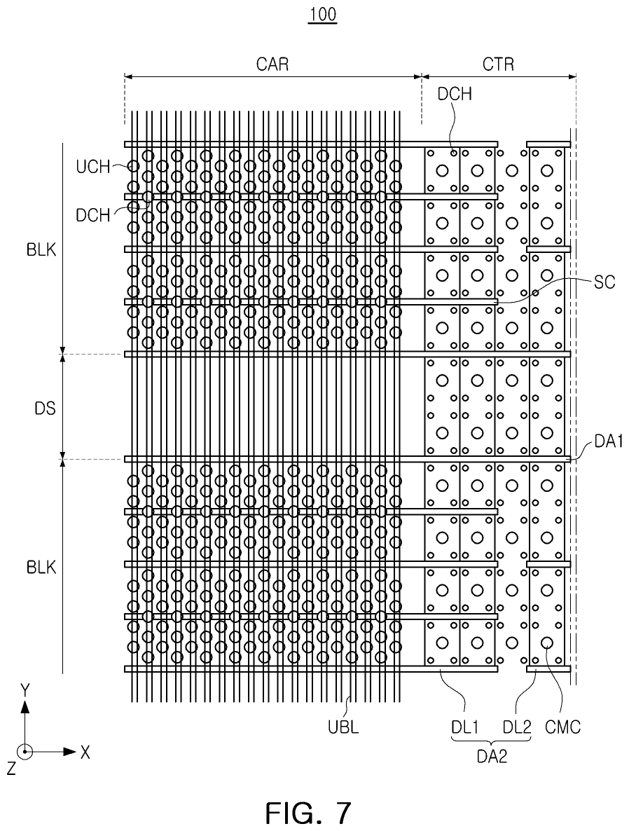

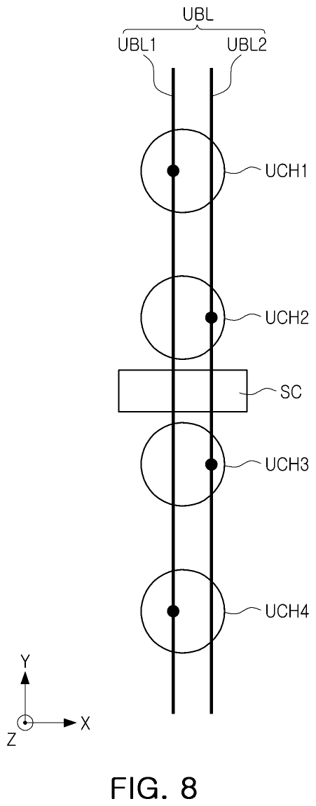

FIGS. 7 and 8 are diagrams illustrating a region of a second stack structure included in a semiconductor device according to an example embodiment.

FIG. 7 is a plan diagram illustrating a portion of the second stack structure included in the semiconductor device 100 according to an example embodiment. The second stack structure described with reference to FIG. 7 may be stacked with the first stack structure described in the aforementioned example embodiment with reference to FIG. 5. Accordingly, the second stack structure may be disposed on the first stack structure in the first direction (Z-axis direction).

The second stack structure may be configured similarly to the first stack structure. Referring to FIG. 6, the second stack structure may include a cell array region CAR and a cell contact region CTR, and in the cell array region CAR, the upper channel structures UCH may be disposed, and in the cell contact region CTR, the cell contacts CMC connected to the upper gate electrode layers may be disposed. In the cell region, a plurality of upper gate electrode layers stacked in the first direction, and a plurality of upper channel structures LCH extending in the first direction and penetrating through or extending into the plurality of upper gate electrode layers may be disposed.

In the cell region, the plurality of blocks BLK may be arranged in the second direction (Y-axis direction), and the plurality of blocks BLK may be distinct from each other by the plurality of first isolation regions DA1 extending in the third direction (X-axis direction). At least one second isolation region DA2 may be disposed in each of the plurality of blocks BLK, and each of the plurality of second isolation regions DA2 may include a first line DL1 and a second line DL2 electrically isolated from each other in the third direction. A portion of the plurality of upper gate electrode layers may be electrically connected as an integrated layer in each of the plurality of blocks BLK through a region between the first line DL1 and the second line DL2.

The second stack structure may include a plurality of dummy channel structures DCH. The plurality of dummy channel structures DCH may be electrically isolated from the plurality of upper bitlines UBL and may not be involved in operation of the semiconductor device 100.

Similar to the plurality of lower bitlines LBL, the plurality of upper bitlines LBL may extend in the second direction and may be arranged in the third direction. Each of the plurality of upper bitlines UBL may be electrically connected to two or more of the upper channel structures UCH, and two or more lower channel structures UCH may be commonly electrically connected to one of the upper bitlines UBL.

Referring to FIG. 8, among the plurality of upper bitlines UBL, a first upper bitline UBL1 and a second upper bitline UBL2 may be disposed adjacent to each other in the third direction. A plurality of upper channel structures UCH1-UCH4 may be disposed below the first upper bitline UBL1 and the second upper bitline UBL2 in the first direction.

Among the plurality of upper channel structures UCH1-UCH4 illustrated in FIG. 8, the first and second upper channel structures UCH1 and UCH2 may be disposed on one side of the upper isolation layer SC in the second direction, and the third and fourth upper channel structures UCH3, UCH4 may be disposed on the other side of the upper isolation layer SC in the second direction. As illustrated in FIG. 8, the first and fourth upper channel structures UCH1 and UCH4 may be electrically connected to the first upper bitline UBL1, and the second and third upper channel structures UCH2 and UCH3 may be electrically connected to the first upper bitline UBL1.

As in an example embodiment illustrated in FIG. 7, at least one through-contact region DS may be disposed between the plurality of blocks BLK in the second stack structure. In the through-contact region DS, lower bitline contacts electrically connected to the plurality of lower bitlines included in the first stack structure below the second stack structure in the first direction may be disposed.

The upper channel structures UCH and the upper gate electrode layers may not be disposed in at least a portion of the through-contact region DS. For example, upper channel structures UCH and upper gate electrode layers may be removed from a region between a pair of first isolation regions DA1 defining a through-contact region DS and adjacent to each other in the second direction through an etching process, and by at least partially filling an insulating material, such as silicon oxide or silicon nitride, the through-contact region DS may be formed. Accordingly, the plurality of lower bitline contacts disposed in the through-contact region DS may not be connected to the upper channel structures UCH and the upper gate electrode layers.

As described in the aforementioned example embodiment with reference to FIG. 5, lower gate electrode layers and lower channel structures may be disposed below the through-contact region DS in the first direction. However, in example embodiments, in the first stack structure, lower gate electrode layers and lower channel structures may not be present in the region disposed below the through-contact region DS.

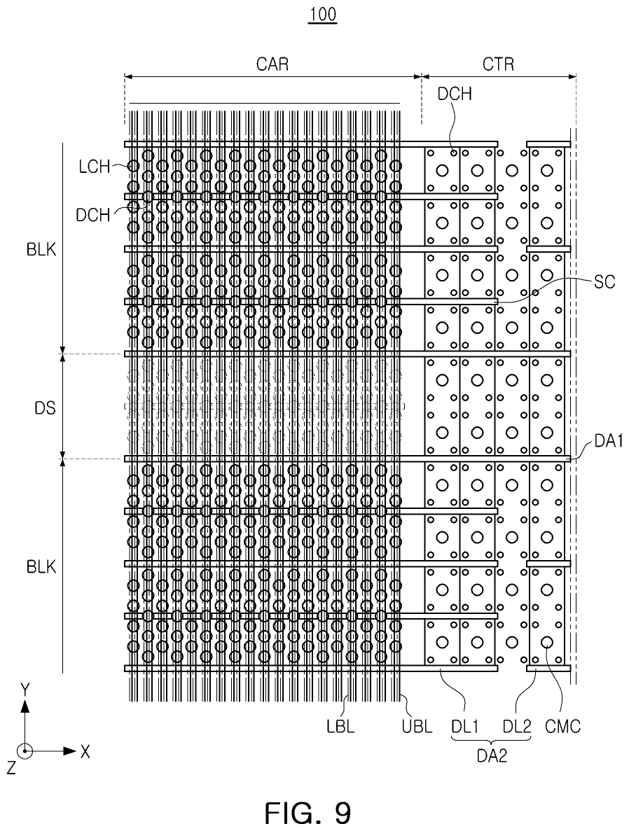

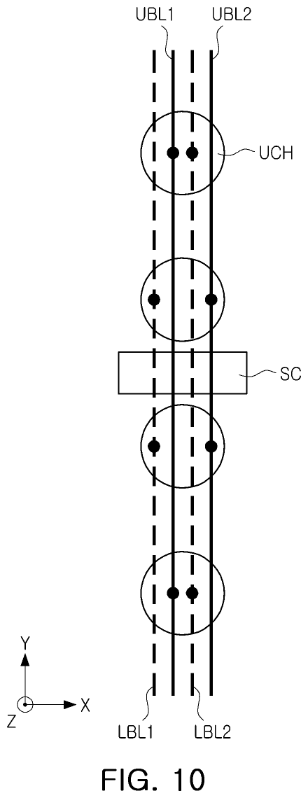

FIGS. 9 and 10 are diagrams illustrating a region of a semiconductor device according to an example embodiment.

FIG. 9 is a plan diagram illustrating a portion of a cell region of a semiconductor device 100 according to an example embodiment. The second stack structure described with reference to FIG. 7 may be stacked with the first stack structure described in the aforementioned example embodiment with reference to FIG. 5. Accordingly, the second stack structure may be disposed on the first stack structure in the first direction (Z-axis direction).

Because the second stack structure is disposed on the first stack structure, the plurality of upper bitlines UBL and the plurality of lower bitlines LBL may be disposed in different positions in the third direction (X-axis direction). Accordingly, a plurality of lower bitline contacts extending in the first direction may penetrate through or extend into the through-contact region DS, may be isolated from the upper bitlines UBL, and may be connected only to the lower bitlines LBL.

Referring to FIG. 10, a first lower bitline UBL1, a first upper bitline UBL1, a second lower bitline LBL2, and a second upper bitline UBL2 may be disposed in order in the third direction. As such, in an example embodiment, the plurality of upper bitlines UBL and the plurality of lower bitlines LBL may be disposed alternately in the third direction and may not overlap each other in the first direction.

In an example embodiment described with reference to FIGS. 9 and 10, upper channel structures UCH may be disposed in the same position as lower channel structures LCH in the second and third directions. The upper channel structures UCH may be disposed to overlap the lower channel structures LCH in the first direction. In other words, one of the lower channel structures LCH may be disposed below one of the upper channel structures UCH.

By disposing the plurality of upper bitlines UBL and the plurality of lower bitlines LBL to not overlap each other in the first direction, the plurality of lower bitline contacts electrically connected to the plurality of lower bitlines LBL may be disposed without interference with the plurality of upper bitlines UBL regardless of positions of the upper channel structures UCH and the lower channel structures LCH. The plurality of lower bitline contacts may be disposed in the through-contact region DS and may be electrically connected to wiring patterns disposed above the upper gate electrode layers in the second stack structure.

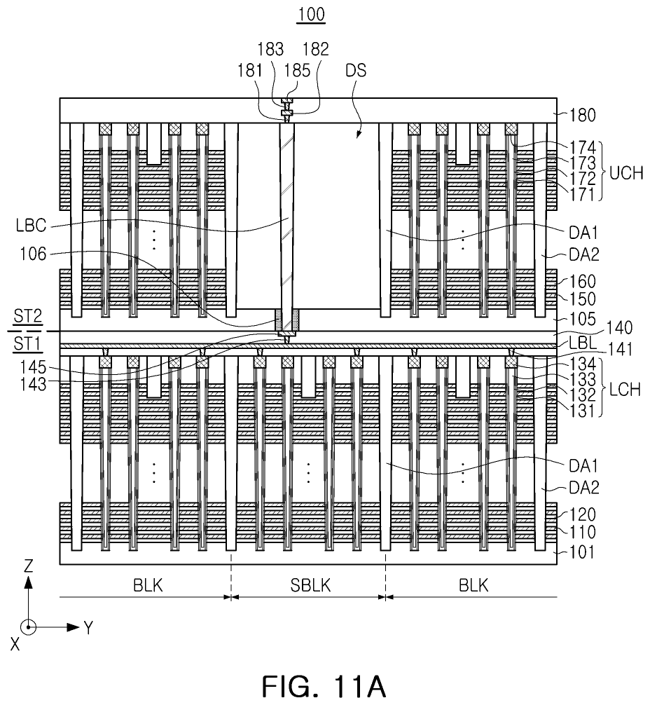

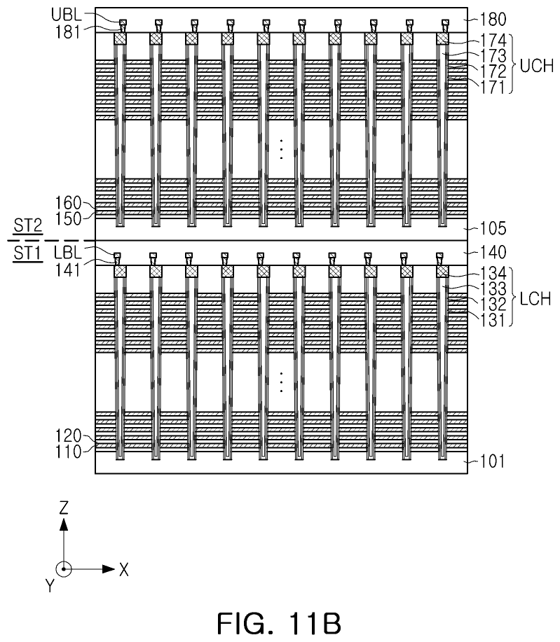

FIGS. 11A and 11B are cross-sectional diagrams illustrating a region of a semiconductor device according to an example embodiment.

FIG. 11A is a diagram illustrating a cross-sectional surface in the second direction (Y-axis direction) in a semiconductor device 100 according to an example embodiment. Referring to FIGS. 9 and 11A together, the semiconductor device 100 may include a first stack structure ST1 and a second stack structure ST2 stacked in the first direction (Z-axis direction).

The first stack structure ST1 may include a plurality of lower gate electrode layers 110 and a plurality of lower insulating layers 120 stacked in the first direction on the first substrate 101, and lower channel structures LCH extending in the first direction and penetrating through or extending into the lower gate electrode layers 110 and the lower insulating layers 120. Each of the lower channel structures LCH may include a lower channel layer 132 electrically connected to the first substrate 101, a lower gate insulating layer 131 disposed between the lower channel layer 132 and the lower gate electrode layers 110, a lower buried insulating layer 133 disposed in the lower channel layer 132, and a lower drain region 134 disposed on the lower channel layer 132.

The plurality of lower gate electrode layers 110 may be divided into a plurality of regions by first isolation regions DA1 and second isolation regions DA2. Also, at least one lower gate electrode layer 110 disposed in an upper portion in the first direction may be divided into a plurality of regions by the upper isolation layer SC. The first interlayer insulating layer 140 may be disposed on the plurality of lower gate electrode layers 110, and the lower bitlines LBL may be disposed in the interlayer insulating layer 140. The lower bitlines LBL may be electrically connected to the lower channel structures LCH through the first lower contact 141.

The lower gate insulating layer 131 may include a tunneling layer, a charge storage layer, a blocking layer, or the like. For example, at least one of the tunneling layer, the charge storage layer, and the blocking layer may be formed to at least partially surround the lower gate electrode layers 110. The lower drain region 134 may be electrically connected to at least one of the lower bitlines LBL through the first lower contact 141. The lower bitlines LBL may extend in the second direction.

The second stack structure ST2 may include a plurality of upper gate electrode layers 150 and a plurality of upper insulating layers 160 stacked on the second substrate 105, and upper channel structures UCH extending in the first direction and penetrating or extending into the upper gate electrode layers 150 and the upper insulating layers 160. Each of the upper channel structures UCH may include an upper channel layer 172 electrically connected to the second substrate 105, an upper gate insulating layer 171 disposed between the upper channel layer 172 and the upper gate electrode layers 150, an upper buried insulating layer 173 disposed in the upper channel layer 172, and an upper drain region 174 disposed on the upper channel layer 172.

The plurality of upper gate electrode layers 150 may be divided into a plurality of regions by first isolation regions DA1 and second isolation regions DA2, and at least one upper gate electrode layer 150 may be divided into a plurality of regions by an upper isolation layer SC. The second interlayer insulating layer 180 may be disposed on the plurality of upper gate electrode layers 150, and the plurality of upper bitlines UBL may be disposed in the second interlayer insulating layer 180. However, because the plurality of lower bitlines LBL and the plurality of upper bitlines UBL are disposed in different positions in the third direction (X-axis direction), the plurality of upper bitlines UBL may not be illustrated in FIG. 11A.

As described above, the second stack structure ST2 may include upper channel structures UCH and a through-contact region DS not including upper gate electrode layers 150. In the through-contact region DS, a space between a pair of first isolation regions DA1 adjacent to each other in the second direction may be at least partially filled with an insulating material.

A lower bitline contact LBC may be disposed in a through-contact region DS. The lower bitline contact LBC may penetrate or extend into the through-contact region DS and the second substrate 105 and may be electrically connected to one of the lower bitlines LBL through a lower pad 145 and a second lower contact 143. The lower bitline contact LBC may be electrically isolated from the second substrate 105 by the second substrate insulating layer 106. The lower bitline contact LBC may be electrically connected to the bonding pad 185 through a first upper contact 181, an upper wiring 182, and a second upper contact 183, disposed in the second interlayer insulating layer 180. In the through-contact region DS, a plurality of lower bitline contacts LBC connected to the lower bitlines LBL may be disposed.

FIG. 11B is a diagram illustrating a cross-sectional surface of one of the plurality of blocks BLK in the third direction in the semiconductor device 100 according to an example embodiment. As described in the aforementioned example embodiment with reference to FIGS. 9 and 10, lower channel structures LCH and upper channel structures UCH are disposed in the same position and may overlap in the first direction.

However, as illustrated in FIG. 11B, the lower bitlines LBL disposed in the first stack structure ST1 and the upper bitlines UBL disposed in the second stack structure ST2 may be disposed in different positions in the third direction. Accordingly, the plurality of lower bitline contacts LBC disposed in the through-contact region DS may extend in the first direction and may be connected to lower bitlines LBL without interference with the upper bitlines UBL and the upper channel structures UCH.

As described with reference to FIGS. 11A and 11B, in an example embodiment, the lower channel structures LCH disposed in the first stack structure ST1 and the upper channel structures UCH disposed in the second stack structure ST2 may be electrically isolated from each other. Also, by connecting the lower bitlines LBL connected to the lower channel structures LCH with the lower bitline contacts LBC disposed in the through-contact region DS of the first stack structure ST1, the lower channel structures LCH may be electrically connected to the bonding pads 185 exposed externally of the second interlayer insulating layer 180. Accordingly, a path to electrically connect the upper channel structures UCH and the isolated lower channel structures LCH to the page buffer may be effectively assured.

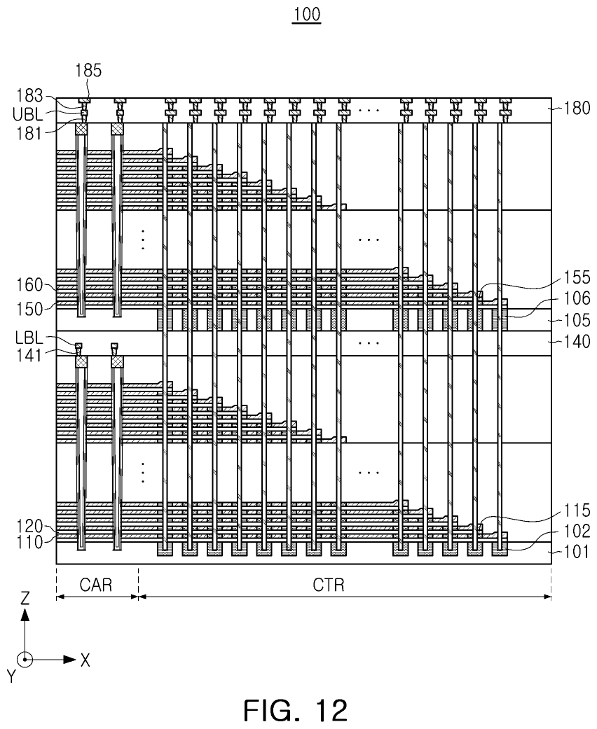

In an example embodiment, because the lower channel structures LCH and upper channel structures UCH are electrically isolated from each other, the plurality of NAND strings disposed in the first stack structure ST1 and the plurality of NAND strings disposed in the second stack structure ST2 may be individually controlled. Accordingly, the lower gate electrode layers 110 and the upper gate electrode layers 150 may share the cell contacts CMC, and accordingly, an area of the cell contact region CTR in which the cell contacts CMC is disposed may be reduced, such that integration density of the semiconductor device 100 may be improved, which will be described in greater detail with reference to FIG. 12.

FIG. 12 is a cross-sectional diagram illustrating a region of a semiconductor device according to an example embodiment.

FIG. 12 is a diagram illustrating a cross-sectional surface in the third direction (X-axis direction) in the semiconductor device 100 according to an example embodiment. Referring to FIG. 12, the semiconductor device 100 may include a first stack structure ST1 and a second stack structure ST2 stacked in the first direction (Z-axis direction).

The first stack structure ST1 and the second stack structure ST2 may have the same structure as described in the aforementioned example embodiment with reference to FIG. 11, and may be divided into a cell array region CAR and a cell contact region CTR in the third direction. The first stack structure ST1 may include a first substrate 101, a plurality of lower gate electrode layers 110, a plurality of lower insulating layers 120, and a plurality of lower channel structures LCH. The lower channel structures LCH may be electrically connected to the lower bitlines LBL extending in the second direction (Y-axis direction) by the first lower contact 141. The lower bitlines LBL may be disposed in the first interlayer insulating layer 140.

The second stack structure ST2 may include a second substrate 105, a plurality of upper gate electrode layers 150, a plurality of upper insulating layers 160, and a plurality of upper channel structures UCH. The upper channel structures UCH may be electrically connected to upper bitlines UBL extending in the second direction by a first upper contact 181. The upper bitlines UBL may be disposed in the second interlayer insulating layer 180 and may be connected to the bonding pads 185 through the second upper contact 183. The upper channel structures UCH and the lower channel structures LCH may be disposed in the cell array region CAR.

At least a portion of the plurality of lower gate electrode layers 110 may extend to different lengths in the third direction, and may provide a pad region having a staircase shape in the cell contact region CTR as illustrated in FIG. 12. The plurality of lower gate electrode layers 110 may be connected to the plurality of cell contacts CMC in the cell contact region CTR. Similarly, at least a portion of the plurality of upper gate electrode layers 150 may extend to different lengths in the third direction and may provide a pad region having a staircase shape in the cell contact region CTR. The plurality of upper gate electrode layers 150 may be electrically connected to the plurality of cell contacts CMC in the cell contact region CTR. As illustrated in FIG. 12, in the cell contact region CTR, the lower gate electrode layers 110 and the upper gate electrode layers 150 may have similar structures.

Each of the plurality of cell contacts CMC may extend between the first stack structure ST1 and the second stack structure ST2. For example, each of the plurality of cell contacts CMC may penetrate or extend into the second substrate 105 and the first interlayer insulating layer 140 and may extend up to the first substrate 101. Each of the plurality of cell contacts CMC may be electrically isolated from the first substrate 101 and the second substrate 105 by the first substrate insulating layer 102 formed on the first substrate 101 and the second substrate insulating layer 106 formed on the second substrate 105. In example embodiments, the plurality of cell contacts a portion of the CMC may not extend to the first substrate 101. Also, in an example embodiment, each of the first substrate insulating layer 102 and the second substrate insulating layer 106 may be formed as an integrated region.

Each of the plurality of cell contacts CMC may be electrically connected to one of the lower gate electrode layers 110 and one of the upper gate electrode layers 150 in common. For example, an nth lower gate electrode layer disposed nth (where n is a natural number) from an upper surface of the first substrate 101 in the first stack structure ST1, and an nth upper gate electrode layer disposed nth from an upper surface of the second substrate 105 in the second stack structure ST2 may be electrically connected to a cell contact CMC. Accordingly, a voltage input to a cell contact CMC may be commonly input to the nth lower gate electrode layer and the nth upper gate electrode layer.

A level on which the nth lower gate electrode layer is disposed from an upper surface of the first substrate 101 may be substantially the same as a level on which the nth upper gate electrode layer is disposed from an upper surface of the second substrate 105 in the first or Z-axis direction. Accordingly, the number of the lower gate electrode layers 110 disposed between the upper surface of the first substrate 101 and the nth lower gate electrode layer may be the same as the number of the upper gate electrode layers 150 disposed between the upper surface of the second substrate 105 and the nth upper gate electrode layer. Also, a length of the nth lower gate electrode layer and a length of the nth upper gate electrode layer may be the same in the third direction.

As such, by commonly connecting one of the lower gate electrode layers 110 and one of the upper gate electrode layers 150 to a cell contact CMC, a length of the cell contact region CTR in the third direction may be shortened, and integration density of semiconductor device 100 may be improved. Even though the semiconductor device 100 is configured such that the lower gate electrode layers 110 and the upper gate electrode layers 150 share the cell contacts CMC, in an example embodiment, by electrically isolating the lower channel structures LCH from the upper channel structures UCH, the memory cells of the first stack structure ST1 and the memory cells of the second stack structure ST2 may be controlled independently.

At least a portion of the plurality of cell contacts CMC may penetrate or extend into gate electrode layers 110 and 150 not electrically connected. Referring to FIG. 12, at least a portion of the gate electrode layers 110 and 150 may include contact isolation regions 115 and 155 formed adjacent to a point through which the plurality of cell contacts CMC penetrates or extends into. Also, in the gate electrode layers 110 and 150, a region connected to the plurality of cell contacts CMC may have a relatively greater thickness than the other regions.

Each of the plurality of cell contacts CMC may be connected to the plurality of bonding pads 186 through a first upper contact 181, an upper wiring 182, and a second upper contact 183, disposed in the second interlayer insulating layer 180. The plurality of bonding pads 186 may be electrically connected to pass transistors described in the aforementioned example embodiment with reference to FIG. 3. In the semiconductor device 100 according to an example embodiment, one of the lower gate electrode layers 110 may be commonly connected to one of the upper gate electrode layers 150 and a pass transistor. Accordingly, the number of pass transistors may be less than the number of gate electrode layers 110 and 150 disposed in a block and stacked in the first direction.

For example, the number of gate electrode layers 110 and 150 disposed in a block may be twice the number of pass transistors. In an example embodiment, when the gate electrode layers 110 and 150 include dummy gate electrode layers not connected to pass transistors, the number of gate electrode layers 110 and 150 may be twice or more the number of pass transistors.

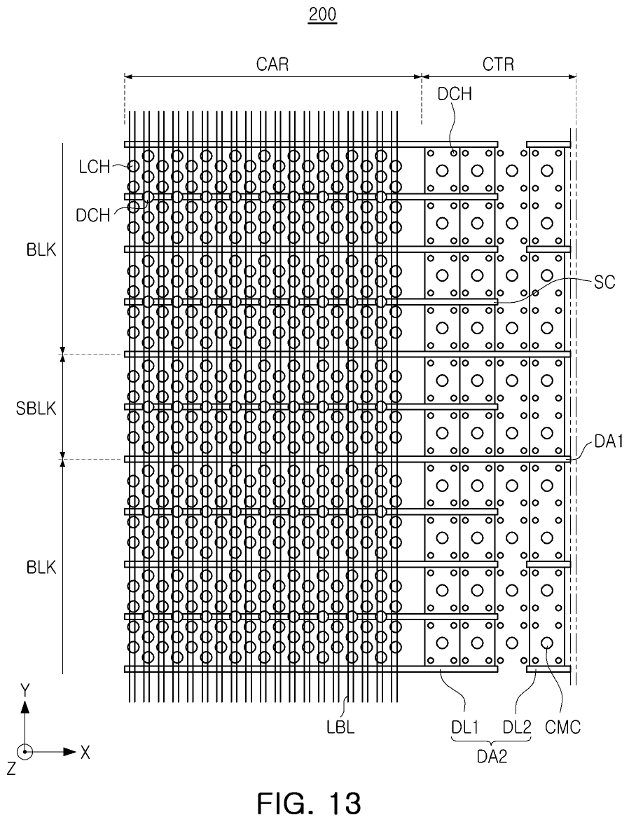

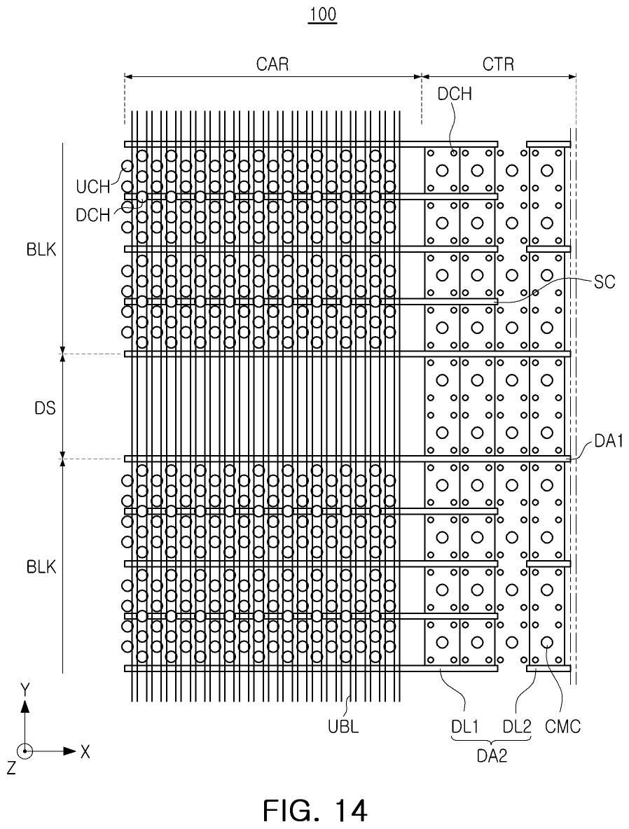

FIG. 13 is a plan diagram illustrating a first layer included in a semiconductor device according to an example embodiment. FIG. 14 is a plan diagram illustrating a second layer included in a semiconductor device according to an example embodiment.

Referring to FIGS. 13 and 14, each of the first stack structure and the second stack structure of the semiconductor device 200 may provide a cell region in which memory cells are disposed, and the cell region may include a cell array region CAR and a cell contact region CTR. For example, in the cell array region CAR, the lower channel structures LCH or the upper channel structures UCH may be disposed, and in the cell contact region CTR, cell contacts CMC electrically connected to at least a portion of the lower gate electrode layers and upper gate electrode layers may be disposed.

In the first stack structure, the lower channel structures LCH may be connected to the lower bitlines LBL, and in the second stack structure, the upper channel structures UCH may be connected to the upper bitlines UBL. The lower bitlines LBL and the upper bitlines UBL may be electrically isolated from each other, and accordingly, the lower channel structures LCH and the upper channel structures UCH may not be connected to each other.

Lower bitline contacts for electrically connecting the lower bitlines LBL to a page buffer of the peripheral circuit may be disposed in the through-contact region DS of the second stack structure. The upper gate electrode layers and the upper channel structures UCH may not be disposed in the through-contact region DS, and accordingly, the lower bitline contacts may be electrically isolated from the memory cells of the second stack structure and may be electrically connected to the lower bitlines LBL.

To electrically isolate the upper bitlines UBL and the lower bitlines LBL from each other, in an example embodiment, the upper bitlines UBL and the lower bitlines LBL may be disposed in different positions in the third direction (X-axis direction). For example, the upper bitlines UBL disposed in the second stack structure and the lower bitlines LBL disposed in the first stack structure may not overlap each other in the first direction.

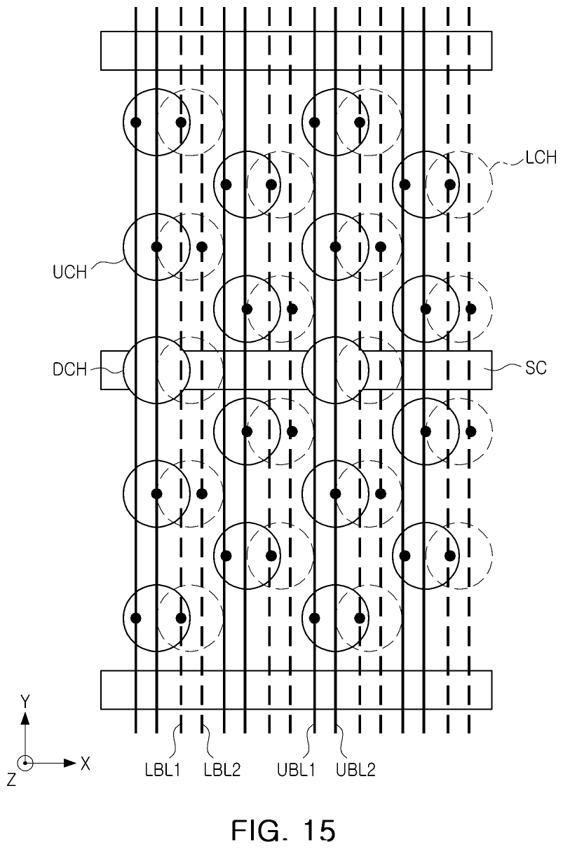

Meanwhile, in an example embodiment illustrated in FIGS. 13 and 14, the bitlines UBL and LBL, and also the upper channel structures UCH and the lower channel structures LCH may be disposed in different positions, which will be described in greater detail with reference to FIG. 15.

FIG. 15 is a plan diagram illustrating a region of a semiconductor device according to an example embodiment.

FIG. 15 is a plan diagram selectively illustrating a region of a semiconductor device according to an example embodiment. Because the semiconductor device according to an example embodiment has a structure in which the lower stack structure and the upper stack structure are stacked with each other, a portion of components illustrated in dotted lines in FIG. 15 may be included in the lower stack structure.

In an example embodiment, the lower bitlines LBL and the upper bitlines UBL may be disposed in different positions in the third direction (X-axis direction), and accordingly, the lower bitlines LBL and the upper bitlines UBL may not overlap each other in the first direction. Referring to FIG. 15, the first lower bitline LBL1 and the second lower bitline LBL2 may be adjacent to each other, and the first upper bitline UBL1 and the second upper bitline UBL2 may be adjacent to each other.

As illustrated in FIG. 15, the lower channel structures LCH and the upper channel structures UCH may be disposed in different positions in the third direction. Accordingly, the lower channel structures LCH and the upper channel structures UCH may not completely overlap each other in the first direction. In an example embodiment illustrated in FIG. 15, the lower channel structures LCH and the upper channel structures UCH may be disposed in the same layout and may be disposed in different positions in the third direction, but an example embodiment thereof is not limited thereto. For example, the layout of lower channel structures LCH and the layout of upper channel structures UCH may be different.

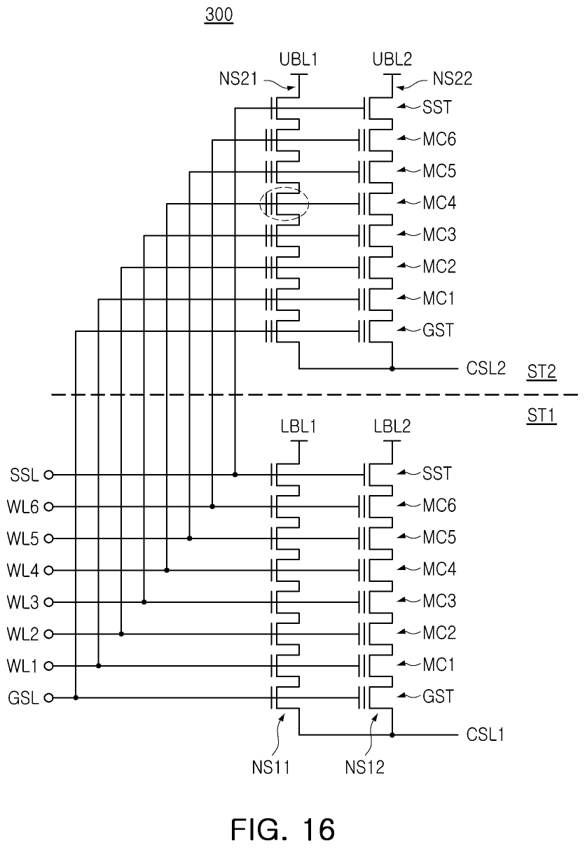

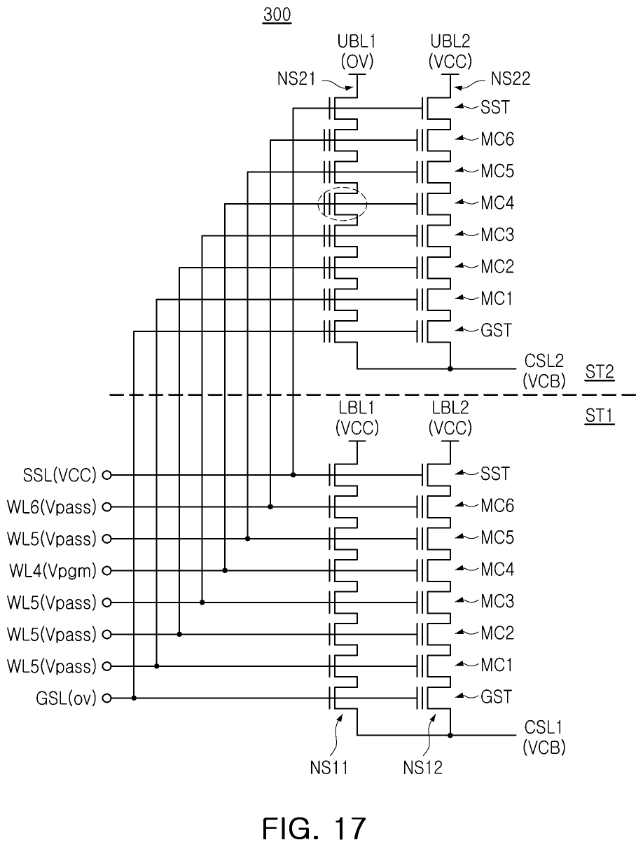

FIGS. 16 and 17 are diagrams illustrating operations of a semiconductor device according to an example embodiment.

Referring to FIG. 16, a semiconductor device 300 according to an example embodiment may include a first stack structure ST1 and a second stack structure ST2 stacked with each other in a direction perpendicular to an upper surface of the substrate. A plurality of NAND strings NS11, NS12, NS21, and NS22 may be disposed in each of the first stack structure ST1 and the second stack structure ST2. In an example embodiment illustrated in FIG. 16, each of the NAND strings NS11, NS12, NS21, and NS22 may include a ground select transistor GST, a string select transistor SST and a plurality of the memory cells MC1-MC6, and the number of the select transistors GST, SST and the number of the memory cells MC1-MC6 may be varied in example embodiments.

The ground select transistor GST may be electrically connected to one of common source lines CSL1 and CSL2, and may be controlled by a voltage input to the ground select line GSL. The string select transistor SST may be electrically connected to one of the bitlines UBL1, UBL2, LBL1, and LBL2, and may be controlled by a voltage input to the string select line SSL. The plurality of the memory cells MC1-MC6 may be controlled by a voltage input to the plurality of wordlines WL1-WL6.

In an example embodiment illustrated in FIG. 16, the NAND strings NS11 and NS12 of the first stack structure ST1 and the NAND strings NS21 and NS22 of the second stack structure ST2 may share a string select line SSL, a ground select line GSL, and the plurality of wordlines WL1-WL6. Also, the NAND strings NS11 and NS12 of the first stack structure ST1 and the NAND strings NS21 and NS22 of the second stack structure ST2 may not share common source lines CSL1, CSL2 and bitlines UBL1, UBL2, LBL1 and LBL2.

As illustrated in FIG. 16, the NAND strings NS11 and NS12 of the first stack structure ST1 may be electrically connected to a first common source line CSL1 and lower bitlines LBL1 and LBL2, and the NAND strings NS21 and NS22 of the second stack structure ST2 may be electrically connected to a second common source line CSL2 and upper bitlines UBL1 and UBL2. Accordingly, although the string select line SSL, the ground select line GSL, and the plurality of wordlines WL1-WL6 are shared, the memory cells MC1-MC6 of the first stack structure ST1 and the memory cells MC1-MC6 of the second stack structure ST2 may be controlled individually.

FIG. 17 is a diagram that illustrates program operation of the semiconductor device 300 according to an example embodiment. In an example embodiment described with reference to FIG. 17, a selected memory cell, which may be a target of a program operation, may be the fourth memory cell MC4 included in the first NAND string NS21 in the second stack structure ST2.

A program voltage VPGM may be input to the fourth wordline WL4, which is a selected wordline connected to the selected memory cell, and a pass voltage VPASS may be input to unselected wordlines connected to unselected memory cells. A ground voltage may be input to a ground select line GSL, and a power voltage VCC higher than the ground voltage may be input to a string select line SSL.

A source bias voltage VCB may be input to each of the first common source line CSL1 and the second common source line CSL2. A ground voltage may be input to the first upper bitline UBL1, and a power voltage VCC may be input to the other bitlines UBL2, LBL1, and LBL2. Accordingly, a voltage of the channel layer may be boosted relatively high in each of the other NAND strings NS11, NS12, and NS22 other than NAND string NS21 including the selected memory cell, and accordingly, a program operation may be executed only for the selected memory cell. Similarly, in an example embodiment, the NAND strings NS11 and NS12 of the first stack structure ST1 and the NAND strings NS21 and NS22 of the second stack structure ST2 may not share the bitlines UBL1, UBL2, LBL1, LBL2 and the common source lines CSL1 and CSL2, the semiconductor device 300 may be implemented in a structure in which the first stack structure ST1 and the second stack structure ST2 share the wordlines WL1-WL6.

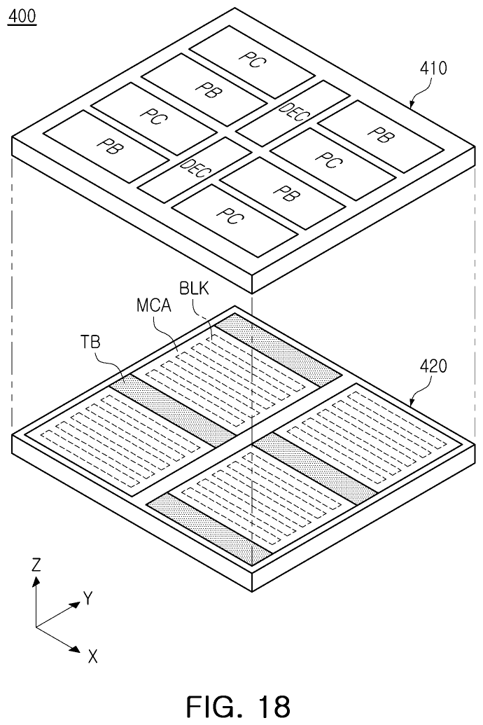

FIG. 18 is a diagram illustrating a memory device according to an example embodiment.

Referring to FIG. 18, a semiconductor device 400 may include a first region 410 and a second region 420 stacked in the first direction (Z-axis direction). The first region 410 may be a peripheral circuit region, and the second region 420 may be a cell region. The first region 410 may include a row decoder DEC, a page buffer PB, and a peripheral circuit PC formed on a substrate. For example, a peripheral circuit PC may include a voltage generator, a source driver, an input/output circuit, or the like.

The second region 420 may include memory cell arrays MCA and a wiring region TB. In the wiring region TB, a plurality of through-wirings for connecting the common source line to a source driver of the first region 410 may be disposed.

Each of the memory cell array MCA may include a plurality of blocks BLK. The plurality of blocks BLK may be arranged in the second direction (Y-axis direction) and may extend in the third direction (X-axis direction). The plurality of blocks BLK may be distinct by the plurality of first isolation regions extending in the third direction, and the plurality of second isolation regions may be disposed in each of the plurality of blocks BLK.

In an example embodiment, the second region 420 may include a first stack structure and a second stack structure stacked in the first direction. The first stack structure may be more spaced apart from the first region 410 than the second stack structure in the first direction. Accordingly, the second stack structure may be disposed between the first stack structure and first region 410 in the first direction.

Each of the first stack structure and the second stack structure may include gate electrode layers, channel structures, and bitlines. The lower bitlines included in the first stack structure may be electrically isolated from upper bitlines included in the second stack structure. The page buffer PB may include a plurality of page buffer circuits, and the page buffer circuit to which lower bitlines are electrically connected may be different from the page buffer circuit to which upper bitlines are electrically connected. Also, the first substrate of the first stack structure and the second substrate of the second stack structure may be electrically connected to different source drivers.

To connect the lower bitlines and the upper bitlines to different page buffer circuits, a through-contact region in which gate electrode layers and channel structures are not disposed may be disposed in the second stack structure. The through-contact region may be at least partially filled with an insulating material, and the lower bitline contacts extending in the first direction and electrically connected to the lower bitlines may be disposed in the through-contact region. As such, by isolating the lower bitlines and the upper bitlines from each other, the gate electrode layers included in the first stack structure and the gate electrode layers included in the second stack structure may share pass transistors included in the row decoder DEC. Accordingly, an area occupied by the row decoder DEC may be reduced, and a length of the memory cell array MCA may be reduced in the third direction, thereby improving integration density of the semiconductor device 400.

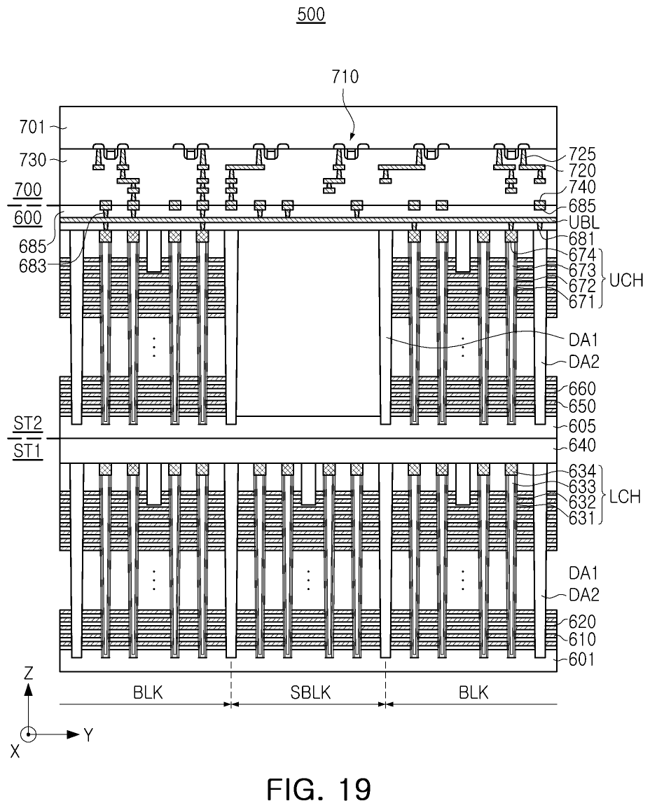

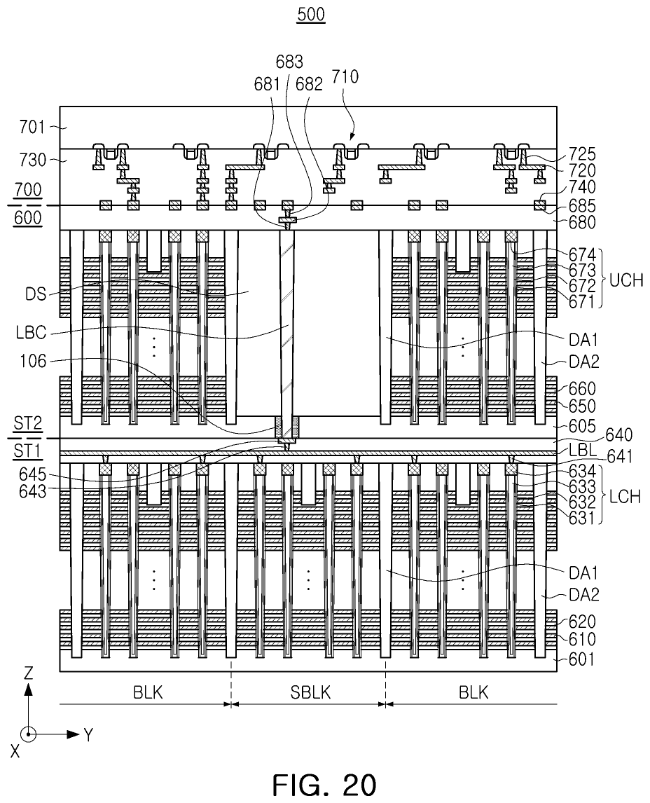

FIGS. 19 and 20 are diagrams illustrating a memory device according to an example embodiment.

Referring to FIGS. 19 and 20, a semiconductor device 500 may include a cell region 600 and a peripheral circuit region 700 stacked in the first direction (Z-axis direction). As illustrated in FIGS. 19 and 20, the peripheral circuit region 700 may be stacked with the cell region 600 in an inverted state.

For example, the semiconductor device 500 may have a chip to chip (C2C) structure. The C2C structure may refer to a structure in which a first chip including cell region 600 may be manufactured on a first wafer, a second chip including peripheral circuit region 700 may be manufactured on a second wafer different from the first wafer, and the first chip and the second chip may be electrically connected to each other using the bonding method. For example, the bonding method may refer to a method of physically and electrically connecting a bonding pad formed on an uppermost wiring pattern layer of the first chip and a bonding pad formed on an uppermost wiring pattern layer of the second chip. For example, when the bonding pad is formed of copper (Cu), the bonding method may be Cu—Cu bonding, and the bonding pad may also be formed of aluminum or tungsten.

The cell region 600 may include a first stack structure ST1 and a second stack structure ST2. The first stack structure ST1 may include the first substrate 601, lower gate electrode layers 610 and lower insulating layers 620 stacked on the first substrate 601, and lower channel structures LCH penetrating or extending into the lower gate electrode layers 610 and the lower insulating layers 620. Each of the lower channel structures LCH may include a lower gate insulating layer 631, a lower channel layer 632, a lower buried insulating layer 633 and a lower drain region 634.

The second stack structure ST2 may include a second substrate 605, an upper gate electrode layers 650 and an upper insulating layers 660 stacked on the second substrate 605, and an upper channel structures UCH penetrating or extending into the upper gate electrode layers 650 and the upper insulating layers 660. A structure of the upper channel structures UCH may be similar to the lower channel structures LCH.

The second substrate 605 may be disposed on the first interlayer insulating layer 640 of the first stack structure ST1. The first substrate 601 may be provided by a wafer, and the second substrate 605 may be provided by a polysilicon substrate formed on the first interlayer insulating layer 640 or a wafer. When the second substrate 605 is provided by a wafer different from the first substrate 601, the first stack structure ST1 and the second stack structure ST2 may be formed in different wafers and may be stacked.

The peripheral circuit region 700 may include a plurality of elements 710 formed on the third substrate 701 and a plurality of wiring patterns 720 electrically connected to the plurality of elements 710. The plurality of wiring patterns 720 may be electrically connected to the plurality of elements 710 through an element contact 725, and the plurality of elements 710 and the plurality of wiring patterns 720 may be disposed in the interlayer insulating layer 730. The plurality of wiring patterns 720 may be physically and electrically connected to the bonding pads 685 of the cell region 600 through the bonding pad 740 formed on the second interlayer insulating layer 730.

First, referring to FIG. 19, the upper channel structures UCH included in the second stack structure ST2 may be electrically connected to the upper bitline UBL by the first upper contact 681 disposed in the second interlayer insulating layer 680. The upper bitline UBL may be electrically connected to the bonding pads 685 through the second upper contact 683, and the bonding pads 685 may be electrically connected to the bonding pads 740 of the peripheral circuit region 700. For example, the plurality of elements 710, which may be electrically connected to the upper bitline UBL by coupling the bonding pads 685 of the cell region 600 to the bonding pads 740 of the peripheral circuit region 700, may be included in the page buffer circuit.

Thereafter, referring to FIG. 20, the lower channel structures LCH included in the first stack structure ST1 may be electrically connected to the lower bitline LBL by the first lower contact 641 disposed in the first interlayer insulating layer 640. The lower bitline LBL may be electrically connected to the lower pad 645 through the second lower contact 643, and the lower pad 645 may be electrically connected to the lower bitline contact LBC. The lower bitline contact LBC may be disposed in the through-contact region DS in which the upper gate electrode layers 650 and the upper channel structures UCH are not disposed in the second stack structure ST2.

The lower bitline contact LBC may be electrically connected to the bonding pads 685 through the first upper contact 681, the upper wiring 682, and the second upper contact 683, disposed in the second interlayer insulating layer 680. The plurality of elements 710, which may be electrically connected to the lower bitline LBL by coupling the bonding pads 685 of the cell region 600 to the bonding pads 740 of the peripheral circuit region 700, may be elements included in the page buffer circuit.

As described with reference to FIGS. 19 and 20, the lower channel structures LCH and the upper channel structures UCH of the cell region 600 may be electrically isolated from each other. The lower channel structures LCH and the upper channel structures UCH may be electrically connected to different page buffer circuits, and a portion of the lower gate electrode layers 610 and the upper gate electrode layers 650 may share cell contacts. Accordingly, the number of pass transistors may be reduced, and by reducing an area of the cell contact region in which the cell contacts are disposed, integration density of the semiconductor device 500 may be improved.

According to the aforementioned example embodiments, a semiconductor device may be implemented with a first semiconductor layer, a first layer including lower gate electrode layers and lower channel structures, a second semiconductor layer, and a second layer including upper gate electrode layers and upper channel structures, the upper channel structures and the lower channel structures may be electrically isolated from each other, and a portion of the upper gate electrode layers and the lower gate electrode layers may be electrically connected to each other. Accordingly, an area of the region in which wordline contacts electrically connected to the upper gate electrode layers and the lower gate electrode layers are disposed may be reduced, and integration density of the semiconductor device may be improved.

While the example embodiments have been illustrated and described above, it will be configured as apparent to those skilled in the art that modifications and variations may be made without departing from the scope in the example embodiment as defined by the appended claims.

1. A semiconductor device, comprising:
a first substrate;
a plurality of lower gate electrode layers stacked on an upper surface of the first substrate in a first direction perpendicular to an upper surface of the first substrate;
a second substrate above the plurality of lower gate electrode layers;
a plurality of upper gate electrode layers stacked on the second substrate in the first direction;
a plurality of lower channel structures extending in the first direction, extending through the plurality of lower gate electrode layers, and electrically connected to the first substrate;
a plurality of upper channel structures extending in the first direction, extending through the plurality of upper gate electrode layers, electrically connected to the second substrate, and electrically isolated from the plurality of lower channel structures;
a plurality of lower bitlines electrically connected to the plurality of lower channel structures and extending in a second direction parallel to the upper surface of the first substrate; and
a plurality of upper bitlines electrically connected to the plurality of upper channel structures and extending in the second direction,
wherein the plurality of lower bitlines and the plurality of upper bitlines are in different positions in a third direction parallel to the upper surface of the first substrate and intersecting the second direction.

2. The semiconductor device of claim 1, further comprising:
at least one through-contact region extending in the third direction and dividing the plurality of upper gate electrode layers into a plurality of regions in the second direction.

3. The semiconductor device of claim 2, further comprising:
a plurality of lower bitline contacts electrically connected to the plurality of lower bitlines and electrically isolated from the plurality of upper bitlines,
wherein the plurality of lower bitline contacts extends into the through-contact region and is electrically connected to the plurality of lower bitlines.

4. The semiconductor device of claim 3, further comprising:
a plurality of upper bitline contacts electrically connected to the plurality of upper bitlines and electrically isolated from the plurality of lower bitlines,
wherein the plurality of upper bitline contacts are electrically connected to the plurality of upper bitline pads, and the plurality of lower bitline contacts are electrically connected to the plurality of lower bitline pads, and
wherein the plurality of upper bitline pads and the plurality of lower bitline pads are in different positions in at least one of the second direction and the third direction.

5. The semiconductor device of claim 1, wherein each of the plurality of lower channel structures and each of the plurality of upper channel structures are disposed in a same position in the second direction and the third direction.

6. The semiconductor device of claim 1, wherein each of the plurality of lower channel structures is in a same position as each of the plurality of upper channel structures, respectively, in the second direction or the third direction.

7. The semiconductor device of claim 1, further comprising:
a plurality of wordline contacts extending in the first direction and extending through at least a portion of the plurality of upper gate electrode layers and the plurality of lower gate electrode layers,
wherein each of the plurality of wordline contacts is commonly electrically connected to one of the plurality of upper gate electrode layers and one of the plurality of lower gate electrode layers.

8. The semiconductor device of claim 7, wherein a length of each of the plurality of wordline contacts is greater than a length of each of the plurality of upper channel structures and each the plurality of lower channel structures, respectively, in the first direction.

9. The semiconductor device of claim 7,
wherein each of the plurality of wordline contacts extends into the second substrate, and
wherein a lower surface of at least one of the plurality of wordline contacts is below an upper surface of the first substrate in the first direction.

10. The semiconductor device of claim 9, further comprising:
a first substrate insulating layer between at least one of the plurality of wordline contacts and the first substrate; and
a second substrate insulating layer between each of the plurality of wordline contacts and the second substrate.

11. A semiconductor device, comprising:
a cell array region including a plurality of lower channel structures extending through a plurality of lower gate electrode layers stacked in a first direction, and a plurality of upper channel structures extending through a plurality of upper gate electrode layers stacked in the first direction and electrically isolated from the plurality of lower channel structures; and
a cell contact region including a plurality of cell contacts electrically connected to the plurality of lower gate electrode layers and the plurality of upper gate electrode layers,
wherein an nth lower gate electrode layer positioned nth in the first direction among the plurality of lower gate electrode layers and a nth upper gate electrode layer positioned nth in the first direction among the plurality of upper gate electrode layers are electrically connected to one of the plurality of cell contacts.

12. The semiconductor device of claim 11,
wherein the cell array region includes a first substrate electrically connected to the plurality of lower channel structures, and a second substrate electrically connected to the plurality of upper channel structures, and
wherein a number of lower gate electrode layers between the nth lower gate electrode layer and an upper surface of the first substrate is equal to a number of upper gate electrode layers between the nth upper gate electrode layer and an upper surface of the second substrate.

13. The semiconductor device of claim 12, wherein a length of the nth lower gate electrode layer is equal to a length of the nth upper gate electrode layer in a second direction parallel to an upper surface of the first substrate.

14. The semiconductor device of claim 11, wherein the cell array region further includes a plurality of lower bitlines electrically connected to the plurality of lower channel structures and extending in a second direction perpendicular to the first direction, and a plurality of upper bitlines electrically connected to the plurality of upper channel structures and extending in the second direction.

15. The semiconductor device of claim 14, wherein the plurality of lower bitlines and the plurality of upper bitlines do not overlap each other in the first direction.

16. The semiconductor device of claim 14,
wherein the plurality of lower gate electrode layers and the plurality of upper gate electrode layers extend in a third direction perpendicular to the first direction and the second direction, and
wherein the plurality of upper bitlines and the plurality of lower bitlines are in different positions in the third direction.

17. The semiconductor device of claim 16, wherein the plurality of lower channel structures and the plurality of upper channel structures are in different positions in the third direction.

18. The semiconductor device of claim 11, further comprising:
a peripheral circuit region including a row decoder electrically connected to the plurality of cell contacts, and a page buffer electrically connected to the plurality of lower channel structures and the plurality of upper channel structures,
wherein the peripheral circuit region is stacked with the cell array region and the cell contact region in the first direction.

19. (canceled)

20. The semiconductor device of claim 18, wherein the page buffer includes a plurality of page buffer circuits, the plurality of lower channel structures are electrically connected to a first ones of the plurality of page buffer circuits, and the upper channel structures are electrically connected to other ones of the plurality of page buffer circuits among the plurality of page buffer circuits.

21. A semiconductor device, comprising:
a plurality of blocks each including a first substrate, a plurality of lower gate electrode layers stacked in a first direction perpendicular to an upper surface of the first substrate, a second substrate above the plurality of lower gate electrode layers, and a plurality of upper gate electrode layers stacked in the first direction on the second substrate;
pass transistors electrically connected to the plurality of lower gate electrode layers and the plurality of upper gate electrode layers; and
a row decoder electrically connected to the pass transistors,
wherein a number of the plurality of lower gate electrode layers and a number of the plurality of upper gate electrode layers included in each of the plurality of blocks are greater than a number of the pass transistors.

22. (canceled)

23. (canceled)
